(19) United States
(12) Patent Application Publication
(10) Pub. No.: US 2017/0345496 A1
(43) Pub. Date: Nov. 30, 2017

(54) ASYMMETRICAL WRITE DRIVER FOR RESISTIVE MEMORY

(71) Applicant: Intel Corporation, Santa Clara, CA (US)

(72) Inventors: Huichu LIU, San Jose, CA (US); Daniel H. MORRIS, Hillsboro, OR (US); Sasikanth MANIPATRUNI, Hillsboro, OR (US); Kaushik VAIDYANATHAN, Santa Clara, CA (US); Ian A. YOUNG, Portland, OR (US); Tanay KARNIK, Portland, OR (US)

(21) Appl. No.: 15/164,665

(22) Filed: May 25, 2016

(51) Int. Cl. G11C 13/00; G11C 11/16

(52) U.S. Cl. CPC G11C 13/0069; G11C 13/0097; G11C 13/0028; G11C 13/0004; G11C 11/161; G11C 11/1675; G11C 11/1657; G11C 13/0002

(57) ABSTRACT

An apparatus is provided which comprises: a select line; a select transistor coupled to a resistive memory element and to the select line; a word-line coupled to a gate terminal of the select transistor; and a current mirror operable to be coupled to the select line during a first mode and to be de-coupled during a second mode.

### BACKGROUND

Robust and repeatable writing of Resistive random access memory (RRAM) requires precise compliance control of write currents and write voltages. This control is complicated because different conditions are required for write-0 versus write-1 (i.e., write asymmetry). Additionally, array wire parasitic and device variation limit functionality of large dense arrays. Existing write driver designs for a 1T1R (one transistor one resistor) RRAM array suffer from multiple supply voltage requirements for the word-line (WL), bit-line (BL), and/or source-line (SL) due to the asymmetrical write conditions of the RRAM element. Here, the term “asymmetrical write conditions” generally refers to different voltage/current conditions that are applied for writing a logic low (also referred to as RESET) and a logic high (also referred to as SET) into an RRAM element. Table 1 provides an example of the various voltages needed for WL, SL, and BL to perform the SET and RESET functions by existing write drivers.

TABLE 1

| | WL | SL | BL |
|---|---|---|---|
| SET | 0.55 V | 0 V | 1.0 V |
| RESET | 1.4 V | 1.4 V | 0 V |

Existing write driver designs also exhibit strong sensitivity to voltage drops on BL/SL, and to WL voltage and transistor variation. These sensitivities require complicated hierarchical BL design with smaller sub-arrays, separate SET/RESET drivers, and BL IR drop detection circuits.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a memory architecture of a resistive memory with asymmetrical write drivers, according to some embodiments of the disclosure.

FIG. 2 illustrates a schematic having a write driver for a 1T1R (one transistor 1 resistor) bit-cell with an n-type select transistor and an n-type current mirror coupled to a select-line (SL), in accordance with some embodiments of the disclosure.

FIGS. 3A-B illustrate functional schematics of the write driver of FIG. 2 during SET and RESET operations, respectively, in accordance with some embodiments.

FIG. 4 illustrates a schematic having a write driver for a 1T1R bit-cell with p-type select transistor and an n-type current mirror coupled to a SL, in accordance with some embodiments of the disclosure.

FIG. 5 illustrates a schematic having a write driver for a 1T1R bit-cell with n-type select transistor and an n-type current mirror coupled to a bit-line (BL), in accordance with some embodiments of the disclosure.

FIG. 6 illustrates a schematic having a write driver for a 1T1R bit-cell with p-type select transistor and an n-type current mirror coupled to a BL, in accordance with some embodiments of the disclosure.

FIG. 7 illustrates a schematic having a write driver for a 1T1R bit-cell with an n-type select transistor and a p-type current mirror coupled to a BL, in accordance with some embodiments of the disclosure.

FIG. 8 illustrates a schematic having a write driver for a 1T1R bit-cell with a p-type select transistor and a p-type current mirror coupled to a BL, in accordance with some embodiments of the disclosure.

FIG. 9 illustrates a schematic having a write driver for a 1T1R bit-cell with an n-type select transistor and a p-type current mirror coupled to a SL, in accordance with some embodiments of the disclosure.

FIG. 10 illustrates a schematic having a write driver for a 1T1R bit-cell with a p-type select transistor and a p-type current mirror coupled to a SL, in accordance with some embodiments of the disclosure.

FIG. 11 illustrates a set of waveforms showing operation of the control signals generated by the write driver, in accordance with some embodiments of the disclosure.

FIG. 12 illustrates a cross-section of a three-dimensional (3D) integrated circuit (IC) having a resistive memory (RRAM) with asymmetrical write drivers, according to some embodiments of the disclosure.

FIG. 13 illustrates a smart device or a computer system or a SoC (System-on-Chip) with a memory architecture having asymmetrical write drivers, according to some embodiments.

### DETAILED DESCRIPTION

Some embodiments describe circuits that accommodate asymmetrical RRAM switching physics and allow for the integration of the devices in large dense arrays. Some embodiments describe a write driver design for a 1T1R bit-cell based on high density CMOS (complementary metal oxide semiconductor) logic compatible oxide-based RRAM by employing current mirror circuitry for current compliance to precisely control the SET resistance (e.g., writing R_{low}), and by applying voltage compliance during RESET (e.g., writing R_{high}) through source follower effect of the write driver.

There are many technical effects of the various embodiments. For example, some embodiments solve the asymmetrical write of RRAM bit-cell at a single VDD (power supply). Some embodiments mitigate the write failures due to the access transistor variation. Various embodiments improve the memory array size efficiency and immunity to IR (voltage) drop on BL/SL. Other technical effects will be evident from the description of various embodiments and figures.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct physical, electrical or wireless connection between the things that are connected, without any intermediary devices. The term “coupled” means either a direct electrical, physical, or wireless connection between the things that are connected or an indirect electrical, physical, or wireless connection through one or more passive or active intermediary devices. The term “circuit” means one or more passive and/or active components that are arranged to cooperate with one another to provide a desired function. The term “signal” means at least one current signal, voltage signal, magnetic signal, electromagnetic signal, or data/clock signal. The meaning of “a,” “an,” and “the” include plural references. The meaning of “in” includes “in” and “on.”

The terms “substantially,” “close,” “approximately,” “near,” and “about,” generally refer to being within +/−20% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For purposes of the embodiments, the transistors in various circuits and logic blocks described here are metal oxide semiconductor (MOS) transistors, which include drain, source, gate, and bulk terminals. The transistors also include Tri-Gate and FinFET transistors, Gate All Around Cylindrical Transistors, Tunneling FET (TFET), Square Wire, or Rectangular Ribbon Transistors or other devices implementing transistor functionality like carbon nano tubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., NMOS, NPN BJT, etc.) and the term “MP” indicates a p-type transistor (e.g., PMOS, PNP BJT, etc.).

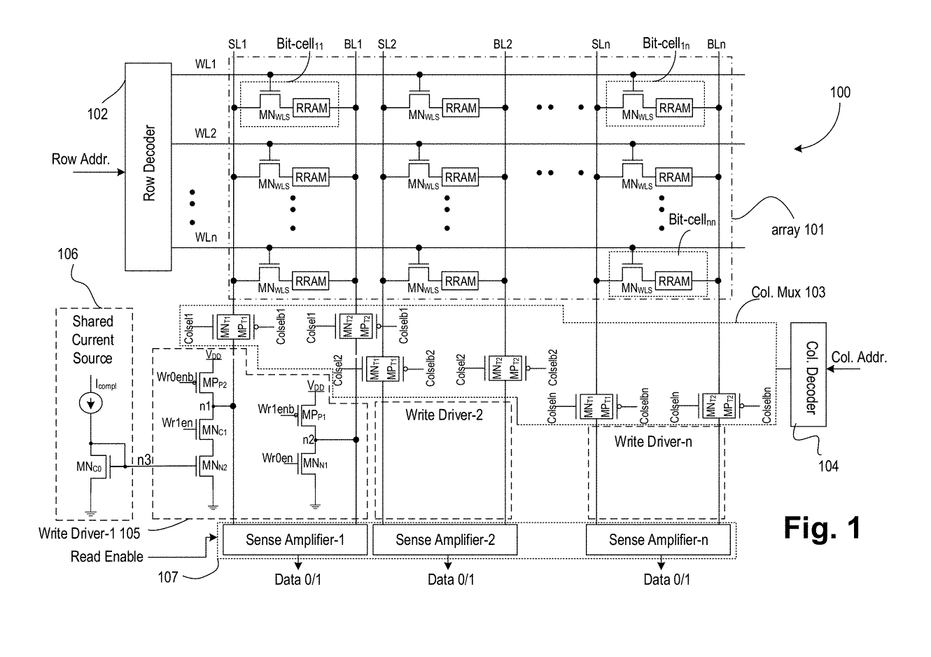

FIG. 1 illustrates memory architecture 100 of a resistive memory with asymmetrical write drivers, according to some embodiments of the disclosure. In some embodiments, memory architecture 100 comprises an array 101 of resistive memory bit-cells, row decoder 102, column multiplexer 103, column decoder 104, asymmetrical write drivers 105, shared current source 106, and sense amplifiers 107.

In some embodiments, array 101 of resistive memory bit-cells comprises bit-cells organized in rows and columns which are accessible by word-lines (WLs), select-line (SLs), and bit-lines (BLs). For example, Bit-cell₁₁ is accessible by WL1, SL1, and BL1; Bit-cell₁ₙ is accessible by WL1, SLn, and BLn (where ‘n’ is a number), and Bit-cellₙₙ is accessible by WLn, SLn, and BLn, where Bit-cell_{xy} corresponds to a bit-cell in row ‘x’ and column ‘y’. In some embodiments, a bit-cell is selected by providing a row address (Row Addr.) and column address (Col. Addr.) to Row Decoder 102 and Col. Decoder 104, respectively. In some embodiments, Row Decoder 102 enables a word-line associated with the to-be selected cell. For example, Row Decoder 102 asserts WL1 to select a bit-cell from row 1 while other word-lines WLs (e.g., WL2 to WLn) are de-asserted. In some embodiments, Col. Decoder 104 enables a word-line associated with a to-be selected cell. For example, Col. Decoder 104 selects column multiplexer(s) to couple the Write Driver-1 to SL1 and BL1 of the selected bit-cell.

In some embodiments, each bit-cell comprises a resistive memory (RRAM) element and a select transistor MN_{WLS} such that one terminal of the RRAM element is coupled to a BL and another terminal of the RRAM element is coupled to the select transistor MN_{WLS}. In some embodiments, the gate terminal of transistor MN_{WLS} is controllable by WL, while the source/drain terminal of transistor MN_{WLS} is coupled to a SL. While array 101 is illustrated with reference to n-type select transistors for the bit-cells, the bit-cells can have p-type select transistors instead in accordance with some embodiments.

In some embodiments, the RRAM element has resistances that depend on the formation and elimination of conduction paths through a dielectric or an electrolyte. In some embodiments, the RRAM element is a spin transfer torque (STT) based magnetic random access memory (MRAM) element. One such MRAM element depends on the relative magnetization polarities of two magnetic layers. In some embodiments, the RRAM element is a phase change memory (PCM), for which the resistivity of a cell depends on the crystalline or amorphous state of a chalcogenide. Other examples of resistive memory include magnetic tunneling junctions (MTJs), conductive bridging RAM (CBRAM), etc. Although the underlying memory element for these and possibly other) resistive memory technologies may vary, methods for writing to and reading from them can be electrically similar and are encompassed by various embodiments of the present disclosure. However, the embodiments are not limited to such and other types of resistive memories can be used too.

In some embodiments, a bit-cell is written with a logic high or logic low by adjusting the resistance of the RRAM element. For example, the resistive element is SET to a first (e.g., low) resistance or RESET to a second (e.g., high) resistance to write a logic high and logic low, respectively, in the RRAM element. The different resistances can be interpreted as different binary values.

In some embodiments, to perform a SET function, the gate terminal of transistor MN_{WLS} of the selected bit-cell is set to logic high by setting the WL for that bit-cell to logic high, and the SL associated with that bit-cell is set to logic low. When the voltage on the BL is higher than the voltage on the SL, a current flows in a first direction through the RRAM element of the selected cell to adjust its resistance to a low resistance. This adjustment in resistance is non-volatile, and as such a logic level is stored in the RRAM element of the selected bit-cell.

In some embodiments, to perform a RESET function, the gate terminal of transistor MN_{WLS} of the selected bit-cell is set to logic high by setting the WL for that bit-cell to logic high, and the SL associated with that bit-cell is set to logic high. In this example, the BL is at logic low level. When the voltage on the SL is higher than the voltage on the BL, a current flows in a second direction through the RRAM element of the selected cell to adjust its resistance to a high resistance. This adjustment in resistance is non-volatile, and as such a logic level is stored in the RRAM element of the selected bit-cell.

In some embodiments, column multiplexer 103 (Col. Mux) is provided to select a column of bit-cells of array 101. In some embodiments, column multiplexer 103 comprises pass-gates or transmission gates (e.g., pair of n-type transistor MN_{T1} and p-type transistor MP_{T1} coupled to a SL, and another pair of n-type transistor MN_{T2} and p-type transistor MP₁₂ coupled to a BL) that can selectively couple a column of bit-cells to a write driver (e.g., Write Driver-1 105).

In some embodiments, a column decoder 104 (Col. Decoder) is provided to decode a column address (Col. Addr.) and then enable appropriate control signal(s) to select the pass-gates of Col. Mux 103. For example, column decoder 104 may select Colsel1 and Colselb1 (which is an inverse of ColSel1) to turn on the pass gate having transistors MN_{T1} and MP_{T1} to couple SL1 and BL1 to Write Driver-1 105. Here, the write drivers are collectively identified as 105.

In some embodiments, each pair of SL and BL is coupled to a corresponding write driver via column multiplexer 103. For example, SL1 and BL1 are coupled to Write Driver-1 via column multiplexer 103, SL2 and BL2 are coupled to Write Driver-2 via column multiplexer 103, and SLn and BLn are coupled to Write Driver-n via column multiplexer 103. In some embodiments, memory architecture 100 comprises Shared Current Source 106 which provides bias voltage (on node n3) to a current mirror based write driver.

Here, write drivers are asymmetric in that the write driver for SL is different than the write driver for BL. For example, Write Driver-1 comprises a current source coupled to Shared Current Source 106. In some embodiments, Shared Current Source 106 comprises a diode connected transistor MN_{C0} and a current supply Icompl coupled to node n3. In some embodiments, node n3 of Shared Current Source 106 is coupled to a write enable transistor stack which can function as a current mirror or constant voltage supply. In some embodiments, the transistor stack comprises transistors MP_{P2}, MN_{C1}, and MN_{N2}, where transistor MP_{P2} is controllable by Wr0enb (inverse of write 0 enable), and where transistor MN_{C1} is controllable by Wr1en (write one enable). In some embodiments, node n1 coupling transistors MP_{P2} and MN_{C1} is coupled to SL1 via Col. Mux 103.

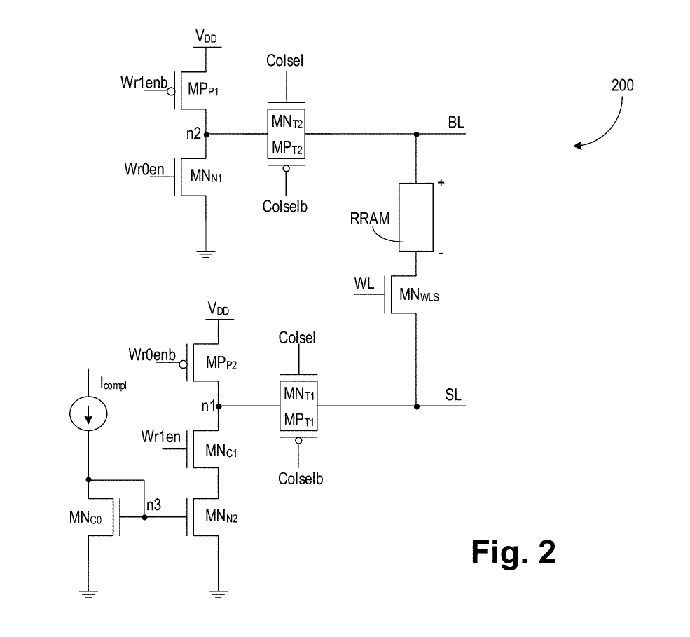

In some embodiments, Write Driver-1 comprises another write enable stack which is coupled to BL1 via Col. Mux 103. In some embodiments, the write enable stack comprises transistors MP_{P1} and MN_{N1} such that node n2 is coupled to BL1 via Col. Mux 103. Various embodiments of write drivers and the shared current source are described with reference to FIGS. 2-11.

Referring back to FIG. 1, in some embodiments, memory architecture 100 comprises sense amplifiers 107 which are coupled to SLs and BLs. For example, Sense Amplifer-1 is coupled to SL1 and BL1, Sense Amplifer-2 is coupled to SL2 and BL2, and Sense Amplifier-n is coupled to SLn and BLn. The sense amplifiers are used during read operation, for example, to detect current or voltage on SLs and BLs to determine the resistive state of the selected bit-cell. As such, sensor amplifiers 107 output digital data (Data 0 or Data 1) depending on the resistive state of the selected bit-cell.

FIG. 2 illustrates schematic 200 having a write driver for a 1T1R (one transistor 1 resistor) bit-cell with an n-type select transistor and an n-type current mirror coupled to a SL, in accordance with some embodiments of the disclosure. It is pointed out that those elements of FIG. 2 having the same reference numbers (or names) as the elements of any other figure can operate or function in any manner similar to that described, but are not limited to such.

Schematic 200 comprises a bit-cell (e.g., Bit-cell₁₁) having n-type select transistor MN_{WLS} coupled in series with a RRAM element. In some embodiments, the positive terminal of RRAM is coupled to BL while the negative terminal of RRAM is coupled to drain/source terminal of transistor MN_{WLS}. The gate terminal of transistor MN_{WLS} is coupled to WL (e.g., WL1). In some embodiments, the source/drain terminal of transistor MN_{WLS} is coupled to SL (e.g., SL1).

Here, the signs ‘+’ and ‘−’ indicate the polarity of the RRAM element. For sample, when the polarity of the voltage across the RRAM element is the same as the RRAM polarity direction, SET occurs (e.g., write logic high, low resistance state); otherwise, RESET occurs (e.g., write logic low, high resistance state). The polarity of the RRAM element is determined by its asymmetrical material stacks (e.g., metal/metal-oxide, including but not limited to, hafnium, hafnium oxides, Tantalum, tantalum oxides, aluminum, aluminum oxides, etc.), where the metal layer location (also known as oxygen-exchange-layer, aligns with the ‘+’ terminal. In some embodiments, SL and BL are coupled to column multiplexers.

In some embodiments, SL is coupled to a pass gate transistors MN_{T1} and MP_{T1}, where transistor MN_{T1} is controlled by Colsel (column select) and transistor MP_{T1} is controlled by Colselb (e.g., an inverse of column select Colsel signal). Likewise, BL is coupled to a pass gate transistors MN_{T2} and MP_{T2}, where transistor MN_{T2} is controlled by Colsel (column select) and transistor MP_{T1} is controlled by Colselb. In some embodiments, write drivers (e.g., Write Driver-1 105) and Shared Current Source 106 are coupled to the column multiplexers.

In some embodiments, the write driver, coupled to BL via pass gate transistors MN_{T2} and MP_{T2}, comprises p-type transistor MP_{P1} and n-type transistor MN_{N1}. In some embodiments, transistors MP_{P1} and MN_{N1} are coupled in series such that their common node n2 is coupled to the column multiplexer pass-gate. In some embodiments, the source terminal of transistor MP_{P1} is coupled to V_{DD} (power supply node) and the source terminal of transistor MN_{N1} is coupled to V_{SS} (ground supply node). In some embodiments, the gate terminal of transistor MP_{P1} is coupled to Wr1enb (an inverse of write 1 enable). Here, signal names and node names are interchangeably used. For example, Wr1enb may refer to control signal Wr1enb or node Wr1enb depending on the context of the sentence. In some embodiments, the gate terminal of transistor MN_{N1} is coupled to Wr0en (write 0 enable).

In some embodiments, another write driver is coupled to the SL via another column multiplexer pass gate. In some embodiments, this other write driver comprises a current mirror which is formed of Shared Current Source 106 and n-type transistor MN_{N2}. In some embodiments, the gate terminal of transistor MN_{N2} is coupled to node n3 of Shared Current Source 106 which is coupled to the diode connected n-type transistor MN_{C0}. In some embodiments, the current mirror transistor MN_{N2} is coupled in series with n-type transistor MN_{C1} which is controllable by Wr1en (write 1 enable). In some embodiments, transistor MN_{N2} is coupled in series with p-type transistor MP_{P2} which is controllable by Wr0enb (inverse of write 0 enable). In some embodiments, the common node n1 of transistors MP_{P2} and MN_{C1} is coupled to pass gate of column multiplexer 103. In some embodiments, the source terminals of transistors MP_{P2} and MN_{N2} are coupled to supply V_{DD} and ground (V_{SS}), respectively.

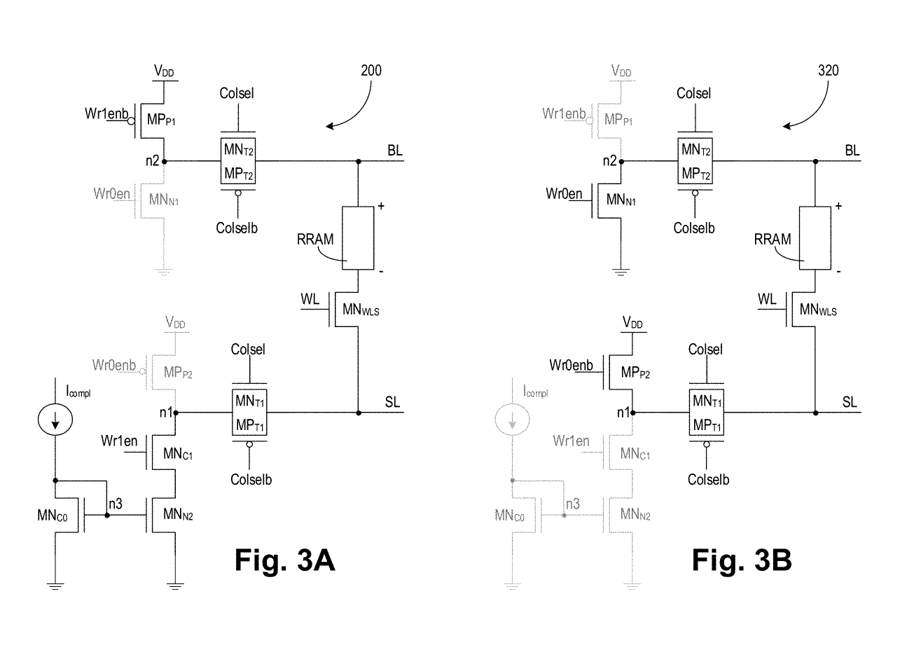

FIGS. 3A-B illustrate functional schematics 300 and 320, respectively, of the write driver of FIG. 2 during SET and RESET operations, respectively, in accordance with some embodiments. It is pointed out that those elements of FIGS. 3A-B having the same reference numbers (or names) as the elements of any other figure can operate or function in any manner similar to that described, but are not limited to such.

FIG. 3A illustrates an equivalent circuit 300 for the SET operation. In some embodiments, to perform the SET function (e.g., to write logic high or ‘1’ in the RRAM element), the control signals are set as follows: Wr0en=Wr1enb=0, Wr0enb=Wr1en=VDD, WL=V_{DD}, Colsel=V_{DD}, and Colselb=0. The light shaded transistors are the disabled transistors during SET function. In some embodiments, during SET function, the current mirror is connected to the column multiplexer via node n1. In some embodiments, during SET function, the difference between the voltages BL and SL (e.g., BL−SL) is positive.

During write operation, WL remains at V_{DD}. For SET (e.g., writing a low resistance R_{low} in the RRAM element), in some embodiments, a voltage pulse of V_{DD} is applied to Colsel which causes the BL voltage to be V_{DD}. During SET operation, in some embodiments, transistor MN_{WLS} is in the linear region of operation and transistor MN_{N2} of the current mirror is in the saturation region of operation. As such, the current through the 1T1R bit-cell is mirrored as I_{compl}. The current equivalent to I_{compl} through the 1T1R bit-cell changes the resistance of the RRAM element from high resistance R_{high} to low resistance R_{low}. In some embodiments, during SET operation, the voltage on the SL follows the drain voltage of the transistor MN_{N2} due to the current mirror control, resulting in a constant current through the RRAM element, which is independent of the gate-voltages Colsel and Colselb of the access transistors (same as column multiplexers) MN_{T1} and MP_{T1}.

FIG. 3B illustrates an equivalent circuit 320 for the RESET operation. In some embodiments, to perform the RESET function (e.g., to write logic low or zero in the RRAM element), the control signals are set as follows: Wr0en=Wr1enb=V_{DD}, Wr0enb=Wr1en=0, WL=V_{DD}, Colsel=V_{DD}, Colselb=0. The light shaded transistors are the disabled transistors during the RESET function. In some embodiments, during RESET function, the current mirror is de-coupled from the column multiplexer. In some embodiments, during RESET function, the difference between the voltages BL and SL (e.g., BL−SL) is negative.

In some embodiments, during RESET operation (e.g., writing a high resistance R_{high} in the RRAM element), BL is pulled down to logical low (i.e., ground) by transistor MN_{N1}. As such, the voltage across the RRAM is (V_{DD}−Vₜₕ), determined by the Vₜₕ drop of the access transistor MN_{WLS}. This voltage compliance is applied for RESET protection, in accordance with some embodiments. FIGS. 3A-B illustrate that asymmetrical write can be achieved with a single V_{DD}, in accordance with some embodiments.

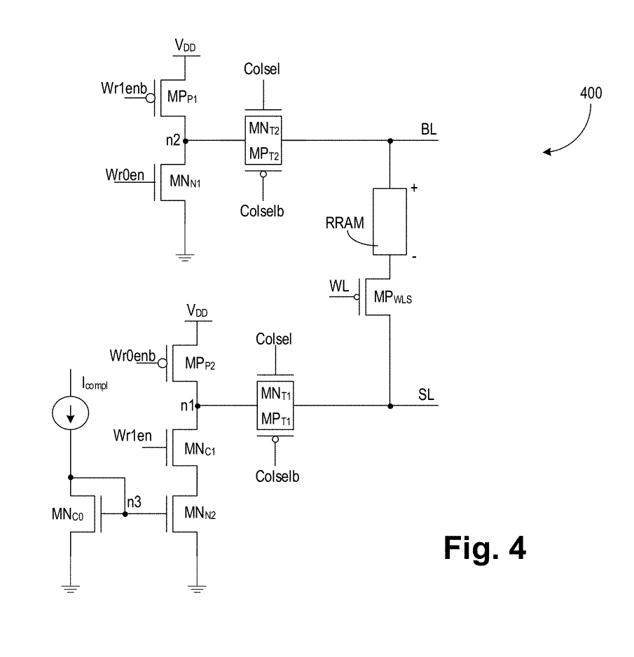

FIG. 4 illustrates schematic 400 having a write driver for a 1T1R bit-cell with p-type select transistor and an n-type current mirror coupled to a SL, in accordance with some embodiments of the disclosure. It is pointed out that those elements of FIG. 4 having the same reference numbers (or names) as the elements of any other figure can operate or function in any manner similar to that described, but are not limited to such. FIG. 4 is similar to FIG. 2.

Here, instead of n-type select transistor for the bit-cell, a p-type select transistor MP_{WLS} is used which is coupled to the RRAM element and to SL. In some embodiments, transistor MP_{WLS} is controlled by WL, and the SET/RESET operations are performed similar to those described with reference to FIG. 2. In some embodiments, the gate terminal of transistor MP_{WLS} is controlled by an inverse of WL (e.g., WLb) to keep the same logic for word-line driver (not shown) as described with reference to FIG. 2. A person skilled in the art would appreciate that p-type transistor MP_{WLS} is turned on when the voltage of WL is V_{DD}−V_{TP} and lower, where V_{TP} is the threshold of p-type transistor MP_{WLS}. Conversely, n-type transistor MN_{WLS} is turned on when the voltage of WL is V_{TN} and above, where V_{TN} is the threshold of n-type transistor MN_{WLS}.

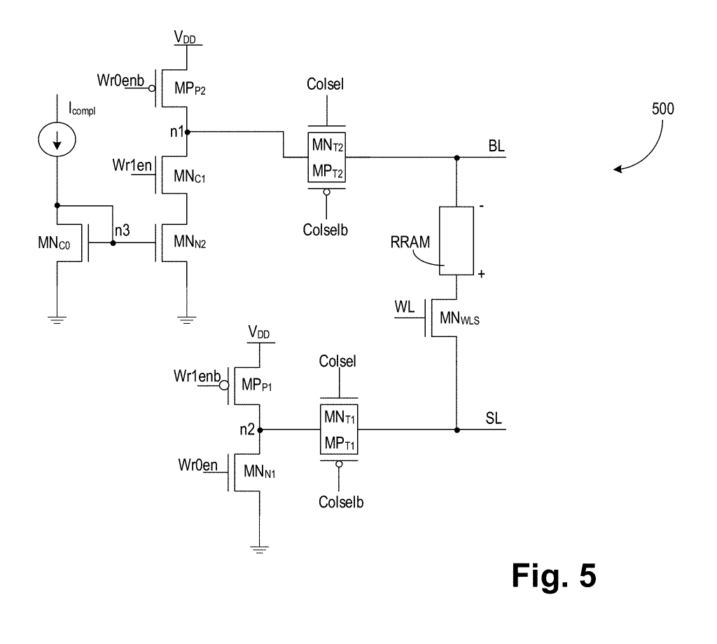

FIG. 5 illustrates schematic 500 having a write driver for a 1T1R bit-cell with n-type select transistor and an n-type current mirror coupled to a bit-line (BL), in accordance with some embodiments of the disclosure. It is pointed out that those elements of FIG. 5 having the same reference numbers (or names) as the elements of any other figure can operate or function in any manner similar to that described, but are not limited to such.

Compared to FIG. 2, here the RRAM element is inverted in that its positive terminal is coupled to the n-type select transistor MN_{WLS} while its negative terminal is coupled to BL. As such, in some embodiments, the current mirror based write driver is coupled to BL via pass gates (e.g., transistors MN_{T2} and MP_{T2}, which are part of column multiplexers), while the other write driver is coupled to SL via pass gates (e.g., transistors MN_{T2} and MP_{T2}, which are part of column multiplexers). The circuit topology and control signals for the write drivers of FIG. 5 are the same as those of FIG. 2 but for being swapped in roles (e.g., the current mirror write driver can be coupled to BL while the other write driver can coupled to SL), in accordance with some embodiments.

In some embodiments, to perform the SET function (e.g., to write logic high or ‘1’ in the RRAM element), the control signals are set as follows: Wr0en=Wr1enb=0, Wr0enb=Wr1en=VDD, WL=V_{DD}, Colsel=V_{DD}, and Colselb=0. In some embodiments, during SET function, the current mirror is connected to column multiplexer via node n1. In some embodiments, during SET function, the difference between the voltages SL and BL (e.g., SL−BL) is positive.

During write operation, WL remains at V_{DD}. For SET (e.g., writing a low resistance R_{low} in the RRAM element), in some embodiments, a voltage pulse of V_{DD} is applied to Colsel which causes the SL voltage to be V_{DD}. (Note, here the threshold drop Vₜₕ across the access transistors MN_{T2} and MP_{T2}, which are part of the column multiplexer, is eliminated with the pass-gates). During SET operation, in some embodiments, transistor MN_{WLS} is in the linear region of operation and transistor MN_{N2} of the current mirror is in the saturation region of operation. As such, the current through the 1T1R bit-cell is mirrored as I_{compl}. Note, the terminals of the RRAM element are reversed compared to the RRAM element of FIG. 2.

Referring back to FIG. 5, the current equivalent to I_{compl} through the 1T1R bit-cell changes the resistance of the RRAM element from high resistance R_{high} to low resistance R_{low}. In some embodiments, during SET operation, the voltage on the BL follows the drain voltage of the transistor MN_{N2} due to the current mirror control, resulting in a constant current through the RRAM element, which is independent of the gate voltages Colsel and Colselb of the access transistors (same as column multiplexers) MN_{T2} and MP_{T2}.

In some embodiments, to perform the RESET function (e.g., to write logic low or ‘0’ in the RRAM element), the control signals are set as follows: Wr0en=Wr1enb=V_{DD}, Wr0enb=Wr1en=0, WL=V_{DD}, Colsel=V_{DD}, Colselb=0. In some embodiments, during RESET function, the current mirror is de-coupled from the column multiplexer. In some embodiments, during RESET function, the difference between the voltages SL and BL (e.g., SL−BL) is negative.

In some embodiments, during RESET operation (e.g., writing a high resistance R_{high} in the RRAM element), the BL is pulled down to logical low (i.e., ground) by transistor MN_{N2}. As such, the voltage across the RRAM is (V_{DD}−Vₜₕ), determined by the Vₜₕ drop of the access transistor MN_{WLS}. This voltage compliance is applied for RESET protection, in accordance with some embodiments. As such, asymmetrical write can be achieved with a single V_{DD}, in accordance with some embodiments.

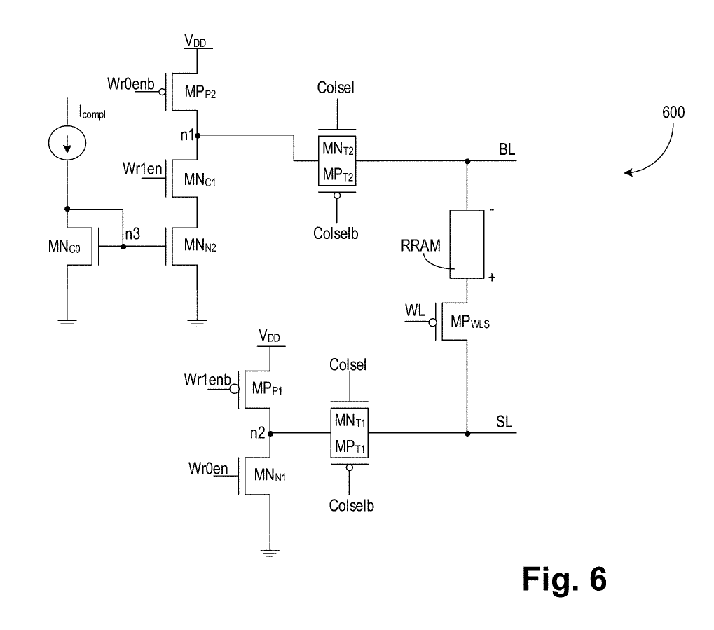

FIG. 6 illustrates schematic 600 having a write driver for a 1T1R bit-cell with p-type select transistor and an n-type current mirror coupled to a BL, in accordance with some embodiments of the disclosure. It is pointed out that those elements of FIG. 6 having the same reference numbers (or names) as the elements of any other figure can operate or function in any manner similar to that described, but are not limited to such. Compared to FIG. 5, here the select transistor is a p-type select transistor MP_{WLS}. In some embodiments, transistor MP_{WLS} is controlled by WL, and the SET/RESET operations are performed similar to those described with reference to FIG. 5. In some embodiments, the gate terminal of transistor MP_{WLS} is controlled by an inverse of WL (e.g., WLb) to keep the same logic for word-line driver (not shown) as described with reference to FIG. 2. A person skilled in the art would appreciate that WL is set low for SET/RESET operations, and set high to un-select the bit-cell.

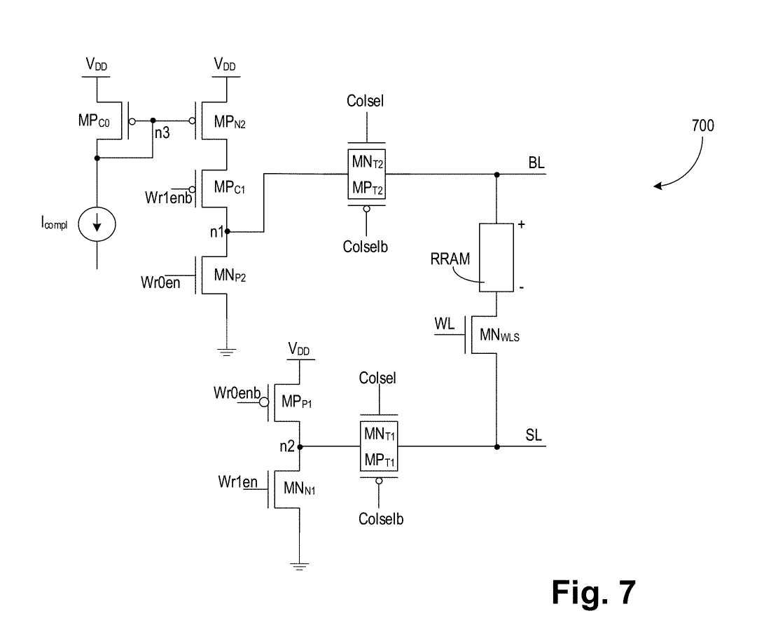

FIG. 7 illustrates schematic 700 having a write driver for a 1T1R bit-cell with an n-type select transistor and a p-type current mirror coupled to a BL, in accordance with some embodiments of the disclosure. It is pointed out that those elements of FIG. 7 having the same reference numbers (or names) as the elements of any other figure can operate or function in any manner similar to that described, but are not limited to such. Schematic 700 is similar to schematic 200 of FIG. 2. Here, in some embodiments, the current mirror based write driver is coupled to BL via pass gates (e.g., transistors MN_{T2} and MP_{T2}, which are part of the column multiplexers), while the other write driver is coupled to SL via pass gates (e.g., transistors MN_{T2} and MP_{T2}, which are also part of the column multiplexers).

In some embodiments, current mirror based write driver is a p-type current mirror. In some embodiments, Shared Current Source 106 comprises a diode-connected p-type transistor MP_{C0} coupled to a current provider I_{compl}. This current is mirrored to p-type transistor MP_{N2} coupled to node n3 (which is coupled to the gate terminal of p-type transistor MP_{C0}). In some embodiments, the p-type transistor MP_{C1} is coupled in series with p-type transistor MP_{C1} which is controllable by Wr1enb (inverse of write 1 enable). In some embodiments, transistor MP_{C1} is coupled in series with n-type transistor MN_{P2} which is controllable by Wr0en (write 0 enable).

In some embodiments, the control signals to the other write driver are also modified in that the p-type transistor MP_{P1} is controllable by Wr0enb (inverse of write 0 enable) while the n-type transistor MN_{N1} is controllable by Wr1en (write 1 enable). In some embodiments, for SET and RESET operations, WL for the bit-cell is set to V_{DD} to enable (or turn on) the n-type select transistor MN_{WLS}. To un-select the bit-cell, WL is set to 0 (e.g., ground). In some embodiments, for SET operation (e.g., to write a logic 1 into the RRAM element), Colsel=V_{DD}, Wr1enb=Wr0en=0, Wr0enb=Wr1en=V_{DD}. In some embodiments, for RESET operation (e.g., to write a logic 0 into the RRAM element), Colsel=V_{DD}, Wr1enb=Wr0en=V_{DD}, Wr0enb=Wr1en=0.

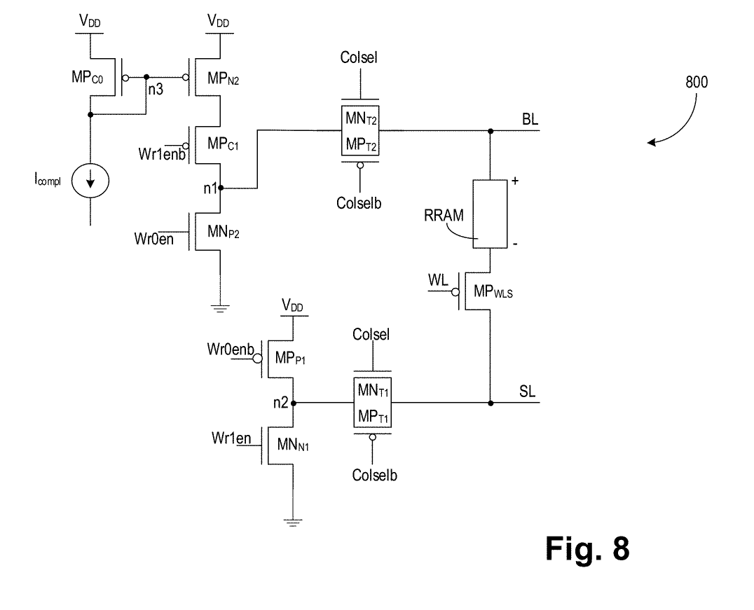

FIG. 8 illustrates schematic 800 having a write driver for a 1T1R bit-cell with a p-type select transistor and a p-type current mirror coupled to a BL, in accordance with some embodiments of the disclosure. It is pointed out that those elements of FIG. 8 having the same reference numbers (or names) as the elements of any other figure can operate or function in any manner similar to that described, but are not limited to such.

Compared to FIG. 7, here the select transistor is a p-type select transistor MP_{WLS}. In some embodiments, transistor MP_{WLS} is controlled by WL, and the SET/RESET operations are performed similar to those described with reference to FIG. 7. In some embodiments, the gate terminal of transistor MP_{WLS} is controlled by an inverse of WL (e.g., WLb) to keep the same logic for word-line driver (not shown) as described with reference to FIG. 7. A person skilled in the art would appreciate that WL is set low for SET/RESET operations, and set high to un-select the bit-cell.

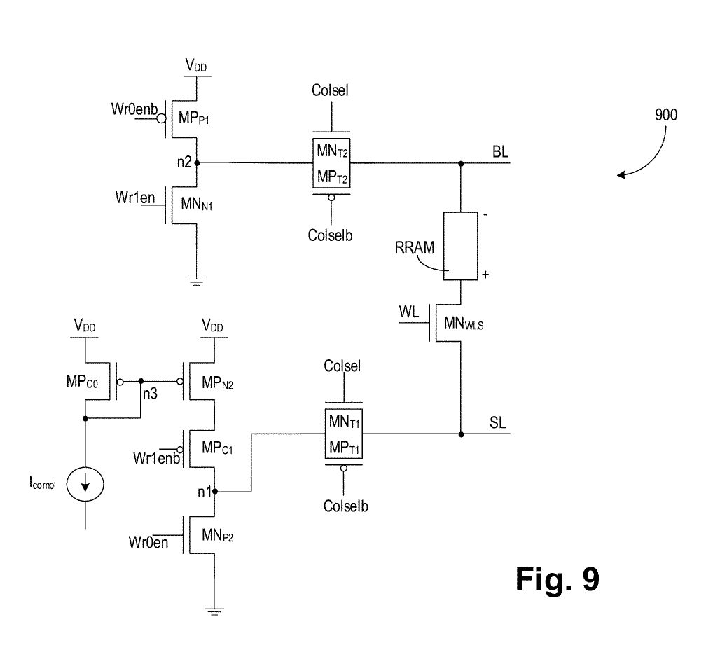

FIG. 9 illustrates schematic 900 having a write driver for a 1T1R bit-cell with an n-type select transistor and a p-type current mirror coupled to a SL, in accordance with some embodiments of the disclosure. It is pointed out that those elements of FIG. 9 having the same reference numbers (or names) as the elements of any other figure can operate or function in any manner similar to that described, but are not limited to such.

In some embodiments, the p-type current mirror based write driver of FIG. 8 is coupled to the SL instead of BL while the other write driver coupled to BL instead of SL. Here, the terminals of the RRAM element are switched compared to the terminals of RRAM element of FIG. 8. For example, the positive terminal of the RRAM element is coupled to the drain/source terminal of the select transistor MN_{WLS}, while the negative terminal of the RRAM element is coupled to the BL. In some embodiments, to perform SET/RESET operations the bit-cell is selected by applying V_{DD} to WL. To un-select the bit-cell, WL is set to V_{SS} (ground).

In some embodiments, during SET operation (e.g., to Write 1 to the RRAM element), Colsel=V_{DD}, Wr1enb=Wr0en=0, Wr0enb=Wr1en=V_{DD}. In some embodiments, during RESET operation (e.g., to write 0 to the RRAM element), Colsel=V_{DD}, Wr1enb=Wr0en=V_{DD}, Wr0enb=Wr1en=0.

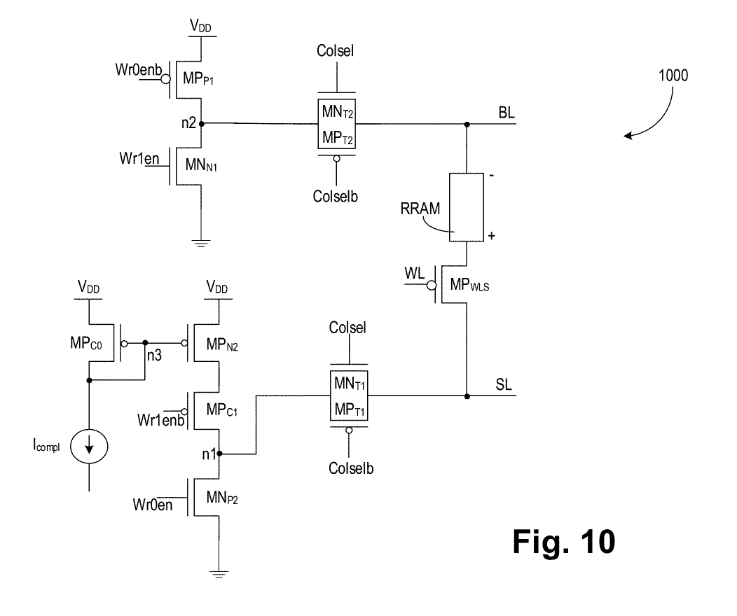

FIG. 10 illustrates schematic 1000 having a write driver for a 1T1R bit-cell with a p-type select transistor and a p-type current mirror coupled to a SL, in accordance with some embodiments of the disclosure. It is pointed out that those elements of FIG. 10 having the same reference numbers (or names) as the elements of any other figure can operate or function in any manner similar to that described, but are not limited to such.

Schematic 1000 is similar to schematic 900 of FIG. 9. Here, the select transistor is replaced with p-type transistor MP_{WLS}. In some embodiments, transistor MP_{WLS} is controlled by WL, and the SET/RESET operations are performed similar to those described with reference to FIG. 9. In some embodiments, the gate terminal of transistor MP_{WLS} is controlled by an inverse of WL (e.g., WLb) to keep the same logic for word-line driver (not shown) as described with reference to FIG. 9. A person skilled in the art would appreciate that WL is set low for SET/RESET operations, and set high to un-select the bit-cell.

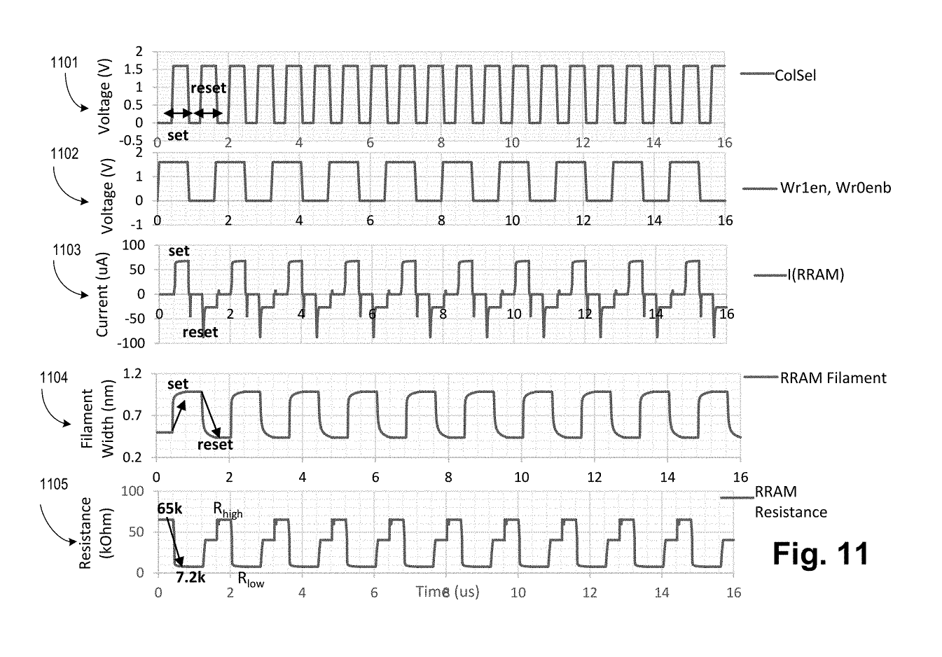

FIG. 11 illustrates a set of waveforms showing operation of the control signals generated by the write driver, in accordance with some embodiments of the disclosure. It is pointed out that those elements of FIG. 11 having the same reference numbers (or names) as the elements of any other figure can operate or function in any manner similar to that described, but are not limited to such.

Here, waveform 1101 is a voltage waveform which illustrates the ColSel signal (column select signal). In this example, the first pulse is for SET operation and the following pulse is for RESET operation, and so on. Waveform 1102 is a voltage waveform which illustrates write enable signals—Wr1en and Wr0enb. Waveform 1103 is a current waveform which illustrates the current through RRAM−I(RRAM). During SET operation, current flows in one direction while during RESET operation current flows in the other direction. Waveform 1104 shows modulating width of the RRAM filament as it increases during SET operation and decreases during RESET operation. Waveform 1105 is a resistance waveform as it changes during SET and RESET operation. For example, during SET operation, the resistance reduces from 65 kilo-Ohms to 7.2 kilo-Ohms, while during RESET operation the resistance increases back to 65 k Ohms.

The write driver of the various embodiments solve the asymmetrical write requirement of the 1T1R RRAM memory. The write driver precisely controls the current and voltage compliance rather than relying on the access transistor gate voltages, in accordance with some embodiments. The asymmetrical write driver of the various embodiments show improvement of the bit-cell number per BL/SL and the array area efficiency. As such, more bit-cells can be packed in a smaller area. The asymmetrical write driver of various embodiments also mitigates the variation impact of the access transistor on RRAM write resistance, and allows for precisely control of the RRAM write resistance, in accordance with some embodiments.

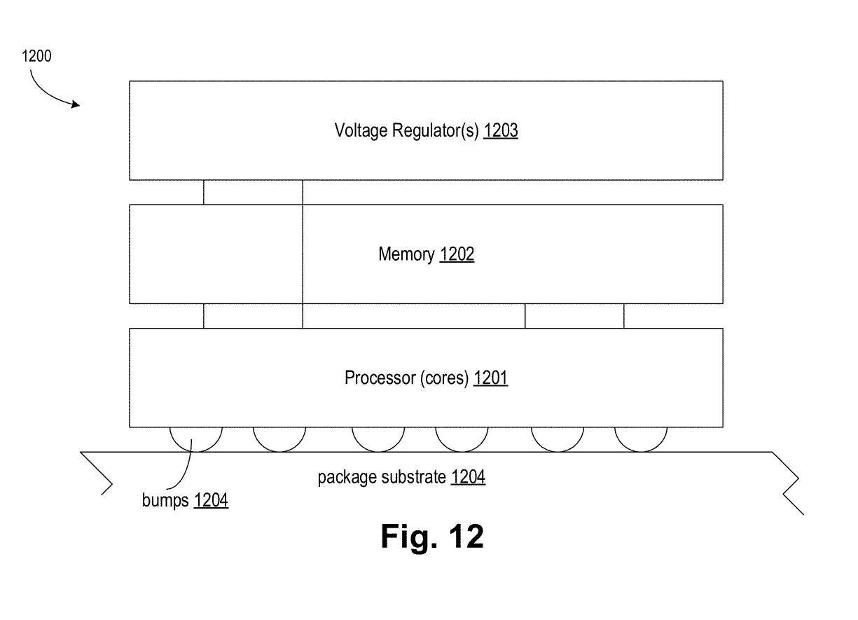

FIG. 12 illustrates a cross-section of a three-dimensional (3D) integrated circuit (IC) 1200 having a RRAM with asymmetrical write drivers, according to some embodiments of the disclosure. In some embodiments, 3D IC 1200 comprises a Processor die 1201 having one or more processor cores, Memory die 1202 (e.g., memory architecture 100 with apparatus to reduce retention failures), Voltage Regulator(s) die 1203, bumps 1204 for coupling the Processor die 1201 to package substrate 1204. 3D IC 1200 may have more or fewer dies shown packaged together in a single package. For example, a communications die having an integrated antenna may also be coupled to one of the dies in 3D IC 1200. The order of the dies may be different for different embodiments. For example, Voltage Regulator(s) 1203 may be sandwiched between Memory die 1202 and Processor die 1201.

In some embodiments, a monolithic 3D IC is used for implementing an RRAM array (e.g., the RRAM and CMOS logic are on the same die). In some embodiments, the RRAM elements reside in the top metal/dielectric layers of the 3D IC or across several metal/dielectric layers, while all the MOSFET transistors in the circuits (e.g., access transistors, drivers, column/row selectors, etc.) reside in the bottom transistor layer of the 3D IC. In some embodiments, the connections to BL, SL, WL are realized in the metal layers.

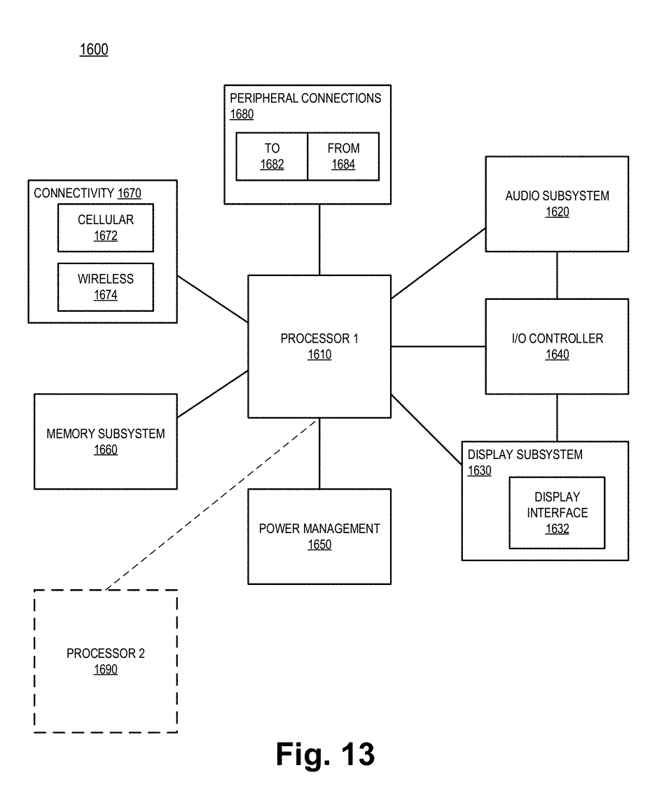

FIG. 13 illustrates a smart device or a computer system or a SoC (System-on-Chip) with memory architecture having asymmetrical write drivers, according to some embodiments. It is pointed out that those elements of FIG. 13 having the same reference numbers (or names) as the elements of any other figure can operate or function in any manner similar to that described, but are not limited to such.

FIG. 13 illustrates a block diagram of an embodiment of a mobile device in which flat surface interface connectors could be used. In some embodiments, computing device 1600 represents a mobile computing device, such as a computing tablet, a mobile phone or smart-phone, a wireless-enabled e-reader, or other wireless mobile device. It will be understood that certain components are shown generally, and not all components of such a device are shown in computing device 1600.

In some embodiments, computing device 1600 includes a first processor 1610 with memory architecture to reduce retention failures in complementary resistive memory, according to some embodiments discussed. Other blocks of the computing device 1600 may also include memory architecture to reduce retention failures in complementary resistive memory according to some embodiments. The various embodiments of the present disclosure may also comprise a network interface within 1670 such as a wireless interface so that a system embodiment may be incorporated into a wireless device, for example, cell phone or personal digital assistant.

In some embodiments, processor 1610 (and/or processor 1690) can include one or more physical devices, such as microprocessors, application processors, microcontrollers, programmable logic devices, or other processing means. The processing operations performed by processor 1610 include the execution of an operating platform or operating system on which applications and/or device functions are executed. The processing operations include operations related to I/O (input/output) with a human user or with other devices, operations related to power management, and/or operations related to connecting the computing device 1600 to another device. The processing operations may also include operations related to audio I/O and/or display I/O.

In some embodiments, computing device 1600 includes audio subsystem 1620, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 1600, or connected to the computing device 1600. In one embodiment, a user interacts with the computing device 1600 by providing audio commands that are received and processed by processor 1610.

In some embodiments, computing device 1600 comprises display subsystem 1630. Display subsystem 1630 represents hardware (e.g., display devices) and software (e.g., drivers) components that provide a visual and/or tactile display for a user to interact with the computing device 1600. Display subsystem 1630 includes display interface 1632, which includes the particular screen or hardware device used to provide a display to a user. In one embodiment, display interface 1632 includes logic separate from processor 1610 to perform at least some processing related to the display. In one embodiment, display subsystem 1630 includes a touch screen (or touch pad) device that provides both output and input to a user.

In some embodiments, computing device 1600 comprises I/O controller 1640. I/O controller 1640 represents hardware devices and software components related to interaction with a user. I/O controller 1640 is operable to manage hardware that is part of audio subsystem 1620 and/or display subsystem 1630. Additionally, I/O controller 1640 illustrates a connection point for additional devices that connect to computing device 1600 through which a user might interact with the system. For example, devices that can be attached to the computing device 1600 might include microphone devices, speaker or stereo systems, video systems or other display devices, keyboard or keypad devices, or other I/O devices for use with specific applications such as card readers or other devices.

As mentioned above, I/O controller 1640 can interact with audio subsystem 1620 and/or display subsystem 1630. For example, input through a microphone or other audio device can provide input or commands for one or more applications or functions of the computing device 1600. Additionally, audio output can be provided instead of, or in addition to display output. In another example, if display subsystem 1630 includes a touch screen, the display device also acts as an input device, which can be at least partially managed by I/O controller 1640. There can also be additional buttons or switches on the computing device 1600 to provide I/O functions managed by I/O controller 1640.

In some embodiments, I/O controller 1640 manages devices such as accelerometers, cameras, light sensors or other environmental sensors, or other hardware that can be included in the computing device 1600. The input can be part of direct user interaction, as well as providing environmental input to the system to influence its operations (such as filtering for noise, adjusting displays for brightness detection, applying a flash for a camera, or other features).

In some embodiments, computing device 1600 includes power management 1650 that manages battery power usage, charging of the battery, and features related to power saving operation. Memory subsystem 1660 includes memory devices for storing information in computing device 1600. Memory can include nonvolatile (state does not change if power to the memory device is interrupted) and/or volatile (state is indeterminate if power to the memory device is interrupted) memory devices. Memory subsystem 1660 can store application data, user data, music, photos, documents, or other data, as well as system data (whether long-term or temporary) related to the execution of the applications and functions of the computing device 1600.

Elements of embodiments are also provided as a machine-readable medium (e.g., memory 1660) for storing the computer-executable instructions (e.g., instructions to implement any other processes discussed herein). The machine-readable medium (e.g., memory 1660) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

In some embodiments, computing device 1600 comprises connectivity 1670. Connectivity 1670 includes hardware devices (e.g., wireless and/or wired connectors and communication hardware) and software components (e.g., drivers, protocol stacks) to enable the computing device 1600 to communicate with external devices. The computing device 1600 could be separate devices, such as other computing devices, wireless access points or base stations, as well as peripherals such as headsets, printers, or other devices.

Connectivity 1670 can include multiple different types of connectivity. To generalize, the computing device 1600 is illustrated with cellular connectivity 1672 and wireless connectivity 1674. Cellular connectivity 1672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 1674 refers to wireless connectivity that is not cellular, and can include personal area networks (such as Bluetooth, Near Field, etc.), local area networks (such as Wi-Fi), and/or wide area networks (such as WiMax), or other wireless communication.

In some embodiments, computing device 1600 comprises peripheral connections 1680. Peripheral connections 1680 include hardware interfaces and connectors, as well as software components (e.g., drivers, protocol stacks) to make peripheral connections. It will be understood that the computing device 1600 could both be a peripheral device (“to” 1682) to other computing devices, as well as have peripheral devices (“from” 1684) connected to it. The computing device 1600 commonly has a “docking” connector to connect to other computing devices for purposes such as managing (e.g., downloading and/or uploading, changing, synchronizing) content on computing device 1600. Additionally, a docking connector can allow computing device 1600 to connect to certain peripherals that allow the computing device 1600 to control content output, for example, to audiovisual or other systems.

In addition to a proprietary docking connector or other proprietary connection hardware, the computing device 1600 can make peripheral connections 1680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. For example, other memory architectures e.g., Dynamic RAM (DRAM) may use the embodiments discussed. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

For example, an apparatus is provided which comprises: a select line; a select transistor coupled to a resistive memory element and to the select line; a word-line coupled to a gate terminal of the select transistor; and a current mirror operable to be coupled to the select line during a first mode and to be de-coupled during a second mode. In some embodiments, the apparatus comprises a first access device coupled to the select line and the current mirror, wherein the first access device is controllable by a column select signal. In some embodiments, the apparatus comprises: a bit-line coupled to the resistive memory element; and a second access device coupled to the bit-line, wherein the second access device is controllable by the column select signal.

In some embodiments, the apparatus comprises a first transistor coupled to the first access device and a supply node, wherein the first transistor is controllable by a write low enable signal. In some embodiments, the apparatus comprises a second transistor coupled to the first access device and the first transistor, wherein the second transistor is controllable by a write high enable signal. In some embodiments, the apparatus comprises a third transistor coupled to the second access device and a supply node, wherein the third transistor is controllable by a write low enable signal. In some embodiments, the apparatus comprises a fourth transistor coupled to the second access device and the third transistor, wherein the fourth transistor is controllable by a write low enable signal.

In some embodiments, the apparatus comprises a column decoder to generate the column select signal. In some embodiments, the first mode is a set mode while the second mode is a reset mode. In some embodiments, the apparatus comprises a sense amplifier coupled to the bit-line and the source-line. In some embodiments, the resistive memory element comprises at least one of: a magnetic tunneling junction (MTJ) device; a phase change memory (PCM) cell; or a resistive random access memory (ReRAM) cell.

In another example, a system is provided which comprises: a processor; a memory coupled to the processor, the memory including an apparatus according to the apparatus described above; and a wireless interface for communicatively coupling the processor to another device. In some embodiments, the processor comprises one or more processor cores, and wherein the memory is an array of resistive memory bit-cells which is located in a different die than the one or more processor cores in a three dimensional (3D) integrated circuit.

In another example, an apparatus is provided which comprises: a select line; a select transistor coupled to a resistive memory element and to the select line; a word-line coupled to a gate terminal of the select transistor; a current mirror; a first access device coupled to the select line and the current mirror, wherein the first access device is controllable by a column select signal; a bit-line coupled to the resistive memory element; and a second access device coupled to the bit-line, wherein the second access device is controllable by the column select signal.

In some embodiments, the current mirror is operable to be coupled to the select line during a first mode and to be de-coupled during a second mode. In some embodiments, the apparatus comprises a second transistor coupled to the first access device and the first transistor, wherein the second transistor is controllable by a write high enable signal. In some embodiments, the apparatus comprises: a third transistor coupled to the second access device and a supply node, wherein the third transistor is controllable by a write low enable signal. In some embodiments, the apparatus comprises: a fourth transistor coupled to the second access device and the third transistor, wherein the fourth transistor is controllable by a write low enable signal.

In another example, a system is provided which comprises: a processor; a memory coupled to the processor, the memory including an apparatus according to the apparatus described above; and a wireless interface for communicatively coupling the processor to another device. In some embodiments, the processor comprises one or more processor cores, and wherein the memory is an array of resistive memory bit-cells which is located in a different die than the one or more processor cores in a three dimensional (3D) integrated circuit.

In another example, a method is provided which comprises: coupling a current mirror to a select line during a first mode; and de-coupling the current mirror from the select line during a second mode, wherein the select line is coupled to a select transistor, wherein the select transistor is coupled to a resistive memory element, wherein the first mode is a set mode while the second mode is a reset mode. In some embodiments, the resistive memory element comprises at least one of: a magnetic tunneling junction (MTJ) device; a phase change memory (PCM) cell; or a resistive random access memory (ReRAM) cell.

In another example, an apparatus is provided which comprises: means for coupling a current mirror to a select line during a first mode; and means for de-coupling the current mirror from the select line during a second mode, wherein the select line is coupled to a select transistor, wherein the select transistor is coupled to a resistive memory element, wherein the first mode is a set mode while the second mode is a reset mode. In some embodiments, the resistive memory element comprises at least one of: a magnetic tunneling junction (MTJ) device; a phase change memory (PCM) cell; or a resistive random access memory (ReRAM) cell.

In another example, a system is provided which comprises: a processor; a memory coupled to the processor, the memory including an apparatus according to the apparatus described above; and a wireless interface for communicatively coupling the processor to another device. In some embodiments, the processor comprises one or more processor cores, and wherein the memory is an array of resistive memory bit-cells which is located in a different die than the one or more processor cores in a three dimensional (3D) integrated circuit.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1. An apparatus comprising:
a select line;
a select transistor coupled to a resistive memory element and to the select line;
a word-line coupled to a gate terminal of the select transistor;
a bit-line coupled to the resistive memory element;
a first write driver to couple to the bit-line, wherein the first write driver comprises first and second transistors coupled in series and controllable by a first write enable and a second write enable, respectively; and
a second write driver, separate from the first write driver, to couple to the select line, wherein the second write driver comprises a current mirror to be coupled to the select line during a first mode and to be de-coupled during a second mode.

2. The apparatus of claim 1 comprises a first access device coupled to the select line and the current mirror, wherein the first access device is controllable by a column select signal.

3. The apparatus of claim 2 comprises:
a second access device coupled to the bit-line, wherein the second access device is controllable by the column select signal.

4. The apparatus of claim 2 comprises a first transistor coupled to the first access device and a supply node, wherein the first transistor is controllable by a write low enable signal.

5. The apparatus of claim 4 comprises a second transistor coupled to the first access device and the first transistor, wherein the second transistor is controllable by a write high enable signal.

6. The apparatus of claim 3 comprises a third transistor coupled to the second access device and a supply node, wherein the third transistor is controllable by a write low enable signal.

7. The apparatus of claim 6 comprises a fourth transistor coupled to the second access device and the third transistor, wherein the fourth transistor is controllable by a write low enable signal.

8. The apparatus of claim 2 comprises a column decoder to generate the column select signal.

9. The apparatus of claim 1, wherein the first mode is a set mode while the second mode is a reset mode.

10. The apparatus of claim 1 comprises a sense amplifier coupled to the bit-line and the source-line.

11. The apparatus of claim 1, wherein the resistive memory element comprises at least one of:
a magnetic tunneling junction (MTJ) device;
a phase change memory (PCM) cell; or
a resistive random access memory (ReRAM) cell.

12. An apparatus comprising:
a select line;
a select transistor coupled to a resistive memory element and to the select line;
a word-line coupled to a gate terminal of the select transistor;
a bit-line coupled to the resistive memory element;
a first write driver to couple to the bit-line, wherein the first write driver comprises first and second transistors coupled in series and controllable by a first write enable and a second write enable, respectively;
a second write driver, separate from the first write driver, to couple to the select line, wherein the second write driver comprises a current mirror;
a first access device coupled to the select line and the current mirror, wherein the first access device is controllable by a column select signal; and
a second access device coupled to the bit-line, wherein the second access device is controllable by the column select signal.

13. The apparatus of claim 12, wherein the current mirror is to be coupled to the select line during a first mode and to be de-coupled during a second mode.

14. The apparatus of claim 12 comprises a second transistor coupled to the first access device and the first transistor, wherein the second transistor is controllable by a write high enable signal.

15. The apparatus of claim 14 comprises a third transistor coupled to the second access device and a supply node, wherein the third transistor is controllable by a write low enable signal.

16. The apparatus of claim 15 comprises a fourth transistor coupled to the second access device and the third transistor, wherein the fourth transistor is controllable by a write low enable signal.

17. A system comprising:
a processor;
a memory coupled to the processor, the memory including:
a select line;
a select transistor coupled to a resistive memory element and to the select line;
a word-line coupled to a gate terminal of the select transistor; and
a bit-line coupled to the resistive memory element;
a first write driver to couple to the bit-line, wherein the first write driver comprises first and second transistors coupled in series and controllable by a first write enable and a second write enable, respectively; and
a second write driver, separate from the first write driver, to couple to the select line, wherein the second write driver comprises a current mirror to be coupled to the select line during a first mode and to be de-coupled during a second mode; and
a wireless interface to communicatively coupling the processor to another device.

18. The system of claim 17, wherein the processor comprises one or more processor cores, and wherein the memory is an array of resistive memory bit-cells which is located in a different die than the one or more processor cores in a three dimensional (3D) integrated circuit.

19. The system of claim 17, wherein the first mode is a set mode while the second mode is a reset mode.

20. The system of claim 17, wherein the resistive memory element comprises at least one of:
magnetic tunneling junction (MTJ) device;
a phase change memory (PCM) cell; or
a resistive random access memory (ReRAM) cell.

21. An apparatus comprising:
a first driver comprising a push-pull circuitry;
a second driver comprising a push-pull circuitry with a current mirror; and
a resistive memory element coupled to source-line and bit-line, wherein the first driver is coupled to the bit-line via a first pass-gate, and wherein the second driver is coupled to the source-line via a second pass-gate.

22. The apparatus of claim 21, wherein the current mirror is an n-type current mirror which is connected to an n-type device of the push-pull circuitry of the second driver.

23. The apparatus of claim 21, wherein the current mirror is a p-type current mirror which is connected to a p-type device of the push-pull circuitry of the second driver.

24. The apparatus of claim 21, wherein the current mirror is shared by multiple drivers in a memory array.

25. The apparatus of claim 21, wherein the resistive memory element comprises at least one of: magnetic tunneling junction (MTJ) device; a phase change memory (PCM) cell; or a resistive random access memory (ReRAM) cell.
